(19) United States
(12) Patent Application Publication
(10) Pub. No.: US 2026/0282523 A1
(43) Pub. Date: Sep. 17, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Sheng-Fu HSU, Hsinchu (TW); Shih-Fan CHEN, Hsinchu City (TW); Lin-Yu HUANG, Hsinchu (TW)

(21) Appl. No.: 19/078,886

(22) Filed: Mar. 13, 2025

(51) Int. Cl. H10D 84/80; H10D 1/47; H10D 1/62; H10D 1/68; H10D 30/47; H10D 62/824; H10D 84/01; H10D 89/60

(52) U.S. Cl. CPC H10D 84/811; H10D 1/474; H10D 1/62; H10D 1/692; H10D 30/475; H10D 62/824; H10D 89/819; H10D 89/911; H10D 84/01

(57) ABSTRACT

An electrostatic discharge (ESD) protection circuit includes a high voltage high-electron-mobility transistor (HEMT) and a plurality of capacitors interconnected with each other in a stacked arrangement. The stacked arrangement of capacitors is connected between a positive supply voltage (VDD) and the gate of the HEMT. A resistor is connected between a negative supply voltage (VSS) and the gate of the HEMT and is connected in series with the stacked capacitor arrangement. During normal operation, the capacitors in the stack are open, and the gate is connected to VSS. When there is an ESD event, the capacitors in the stack are shorted, and the gate is connected to VDD so that the gate of the HEMT receives a voltage corresponding to an ESD event as an input voltage. As a result, the high voltage HEMT may be turned on to conduct and dissipate ESD current.

### BACKGROUND

Electrostatic discharge (ESD) is a concern for semiconductor integrated circuits (ICs). If not handled properly, an ESD event can result in a high voltage that may damage device circuitry of a semiconductor device. To prevent ESD-related damage, a semiconductor device may include an ESD protection circuit. The ESD protection circuit may be operable to divert electrical current away from device circuitry of the semiconductor device during an ESD event, thereby protecting the device circuitry from being damaged by the ESD event.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIG. 2 is a diagram of an example implementation of a high-electron-mobility transistor (HEMT) described herein.

FIG. 3 is a diagram of an example implementation of a layout of the semiconductor device described herein.

FIGS. 4A-4C are diagrams of an example implementation of forming a semiconductor device described herein.

FIG. 5 is a diagram of an example implementation of a capacitor described herein.

FIG. 6 is a diagram of an example implementation of a capacitor arrangement described herein.

FIG. 7 is a diagram of an example implementation of a resistor described herein.

FIGS. 8A-8E are diagrams of an example implementation of a layout of the semiconductor device described herein.

FIGS. 9A-9C are diagrams of an example implementation of forming a semiconductor device described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gallium nitride (GaN)-based materials have several advantageous electrical, mechanical, and chemical properties, such as wide band gap, high breakdown voltage, high electron mobility, large elastic modulus, high piezoelectric and piezoresistive coefficients, etc., as well as chemical inertness. Such advantages make GaN-based materials attractive for making semiconductor devices such as power management devices, high brightness light-emitting diodes (LEDs), and other types of semiconductor devices.

GaN-based high-electron-mobility transistors (HEMTs) are HEMTs that are formed on a GaN substrate. GaN-based HEMTs may offer high operating voltages (e.g., 20 volts to 1200 volts or greater) and high frequency switching speeds for radar, power switching, and millimeter wave communications, among other examples. Electrostatic discharge (ESD) protection is needed for high voltage GaN-based HEMTs. However, there is a lack of sufficient drain to source ESD protection in high voltage GaN-based HEMTs. For example, in a high voltage GaN-based HEMT where the gate of the HEMT is tied to ground (e.g., negative supply voltage (VSS)), the channel of the high voltage GaN-based HEMT device may not turn on during an ESD event because the gate-to-source voltage (Vgs) resulting from the input voltage (e.g., VSS) is smaller than the threshold voltage (Vt) of the high voltage GaN-based HEMT. As a result, this circuit is unable to dissipate ESD current, and ESD performance is poor. In a high voltage GaN-based HEMT where the gate is tied to a positive supply voltage (VDD), the channel of the high voltage GaN-based HEMT device may turn on during an ESD event because Vgs resulting from the input voltage (e.g., VDD) is greater than the threshold voltage (Vt) of the high voltage GaN-based HEMT. As a result, this circuit may be able to dissipate ESD current and ESD performance may be acceptable. However, in the high voltage GaN-based HEMT where the gate is tied to VDD, there is high leakage current during normal operation because the channel is always on.

In some implementations described herein, an ESD protection circuit includes a high voltage GaN-based HEMT and a plurality of capacitors interconnected with each other in a stacked arrangement. The stacked arrangement of capacitors is connected between VDD and the gate of the HEMT (e.g., before the high side of the gate of the HEMT). In addition, a resistor is connected between VSS and the gate of the HEMT and is connected in series with the stacked capacitor arrangement. During normal operation, the capacitors in the stack are open, and the gate is pulled (e.g., connected) to VSS. As a result, the stacked capacitors provide sufficient voltage drop between VDD and the gate of the high voltage GaN-based HEMT during normal operation so that current leakage may be limited and/or prevented. When there is an ESD event, the capacitors in the stack are shorted, and the gate is pulled (e.g., connected) to VDD so that the gate of the HEMT receives a voltage corresponding to an ESD event as an input voltage. As a result, the high voltage GaN-based HEMT may be successfully turned on to conduct and dissipate ESD current. Accordingly, an ESD protection device that includes a stacked arrangement of capacitors interconnected with each other and connected between VDD and the gate of the HEMT may fully dissipate the ESD event current or provide functionality during normal operating conditions, leading to improved performance and adequate responses to ESD events.

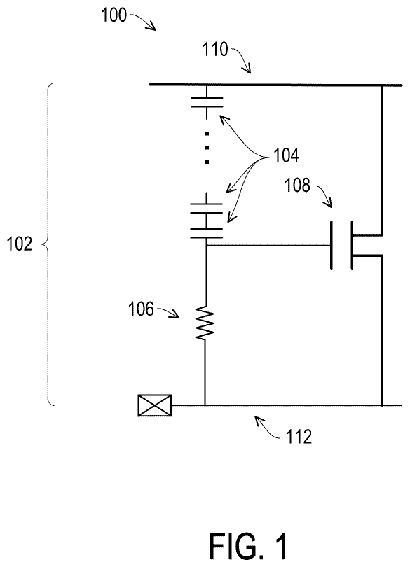

FIG. 1 is a diagram of an example semiconductor device 100 described herein. The semiconductor device 100 may include a logic device (e.g., a processor, a central processing unit (CPU), a graphics processing unit (GPU)), a memory device (e.g., a dynamic random access memory (DRAM) device, a static random access memory (SRAM) device), a display panel device (e.g., a display panel driver including a driver integrated circuit (IC), a line driver IC, a level shifter IC), and/or another type of semiconductor device 100 that includes high voltage semiconductor devices.

An example semiconductor device 100 may include a device circuit, and an ESD protection circuit 102, among other types of circuits. In some implementations, the device circuit includes a high voltage device circuit and high voltage transistors. A high voltage transistor may include a high voltage HEMT, a high voltage planar transistor, a high voltage fin field effect transistor (finFET), a high voltage nanostructure (e.g., a gate all around (GAA) transistor, a nanowire transistor, a nanosheet transistor, a multi-bridge channel transistor, a nanoribbon transistor), and/or another type of high voltage transistor that is configured to operate at high voltages (e.g., greater than 40 volts, for example).

The ESD protection circuit 102 may include a circuit including a plurality of capacitors 104 in a stacked arrangement, a resistor 106, and a high voltage HEMT 108 configured to provide ESD protection for the device circuit against high voltage spikes, high voltage surges, and/or other types of high voltage events. In some implementations, the high voltage HEMT 108 of the ESD protection circuit 102 performs normal operations (e.g., operations corresponding to power management, LED brightness, etc. for semiconductor devices). When not performing normal operations, the high voltage HEMT 108 may protect itself (e.g., perform self-protection) against ESD events and/or protect other devices against ESD events. As used herein, “high voltage” for the high voltage HEMT 108 may be included in the range of approximately 20 volts to approximately 1200 volts. However, other values for the voltage range are within the scope of the present disclosure.

As shown in FIG. 1, the ESD protection circuit 102 is connected to a supply voltage source 110, providing a positive supply voltage (e.g., VDD) to the ESD protection circuit 102. The ESD protection circuit 102 is connected to a ground (e.g., negative supply voltage (VSS)) voltage source 112. The plurality of capacitors 104 in the stacked arrangement may be connected to each other in series and connected between the supply voltage source 110 (e.g., VDD) and a gate of the high voltage HEMT 108. The resistor 106 may be connected between the ground voltage source 112 and the gate of the high voltage HEMT 108. The resistor 106 is connected in series with the plurality of capacitors 104. A first source/drain region of the high voltage HEMT 108 is connected to the supply voltage source 110, and a second source/drain region of the high voltage HEMT 108 is connected to the ground voltage source 112. “Source/drain region” may refer to a source or a drain, individually or collectively, depending upon the context. Although one ESD protection circuit 102 is shown, in some implementations, a semiconductor device 100 may include more than one ESD protection circuit 102.

In operation, when an input voltage satisfying a threshold to qualify for an ESD event (e.g., a voltage satisfying a breakdown voltage (BV)) is applied to the supply voltage source 110, the capacitors are shorted. As a result, the gate of the high voltage HEMT 108 receives the input voltage from the supply voltage source 110, and the high voltage HEMT 108 is turned on. The high voltage HEMT 108 is turned on because the gate-to-source voltage (Vgs) resulting from the input voltage to the supply voltage source 110 is greater than the threshold voltage (Vt) of the high voltage HEMT 108. A dissipated voltage corresponding to the voltage inputted to the supply voltage source 110 is transmitted from the second source/drain region of the high voltage HEMT 108 to the ground voltage source 112.

During normal operation, the capacitors 104 in the stacked arrangement are open, and the gate is pulled (e.g., connected) to the ground voltage source 112, and does not receive a voltage from the supply voltage source 110 since the capacitors 104 are open. As a result, the stacked capacitors provide sufficient voltage drop between the supply voltage source 110 and the gate of the high voltage HEMT 108 during normal operation. As a result, current leakage may be reduced and/or prevented in comparison to an arrangement where a gate of a HEMT is connected to the supply voltage source 110 without an intervening stacked arrangement of a plurality of capacitors. Accordingly, an ESD protection circuit 102 that includes a stacked arrangement of capacitors 104 interconnected with each other and connected between the supply voltage source 110 (e.g., VDD), and the gate of the high voltage HEMT 108 may fully dissipate ESD event current or provide functionality during normal operating conditions, leading to improved performance and adequate responses to ESD events.

In some implementations, a quantity of the plurality of capacitors 104 in the stacked arrangement is included in a range of 3 to 10. For example, a quantity of capacitors 104 in the stacked arrangement may be greater than or equal to 3, and less than or equal to 10, such that there may be 3 to 10 capacitors 104 in the stacked arrangement. If the quantity is less than 3, then the stacked arrangement of capacitors 104 may be unable to sustain enough voltage for normal operation of the high voltage HEMT 108. If the quantity is greater than 10, chip area may be unnecessarily consumed by the capacitors 104. However, other values for the quantity of capacitors 104 in a stack are within the scope of the present disclosure. In some implementations, each capacitor 104 may be rated at a breakdown voltage (BV) included in a range of approximately 5 volts to approximately 20 volts. However, other values for the breakdown voltage range are within the scope of the present disclosure.

In some implementations, the structure of each capacitor 104 is designed to achieve a small lateral footprint, and may include a metal-insulator-metal (MIM) layer stack in which bottom electrode layers and top electrode layers (e.g., top and bottom conductive layers) are arranged in an alternating manner and separated by insulator layers. In some cases, the size of a capacitor 104 may be increased in a vertical direction such that the capacitor 104 extends through a plurality of layers in a semiconductor device 100 to form a deep trench capacitor (DTC). A DTC is a type of capacitor structure that is formed in a deep trench in a semiconductor device such that the electrode layers and insulator layers extend along, and conform to, a profile of the deep trench. This enables the area of the conductive electrode layers to be increased (which increases the capacitance) with minimal increase in the lateral size of the capacitor structure. The trench of a DTC structure is typically formed to have a high aspect ratio between the depth of the trench and the width of the trench.

In some implementations, each capacitor 104 may include a metal-oxide-metal (MOM) capacitor in an interdigitated arrangement of top and bottom metal layers with oxide layers disposed between the top and bottom metal layers (e.g., in a vertical arrangement). The metal layers of different capacitors 104 may be connected to each other through a lateral (e.g., horizontal) metal line.

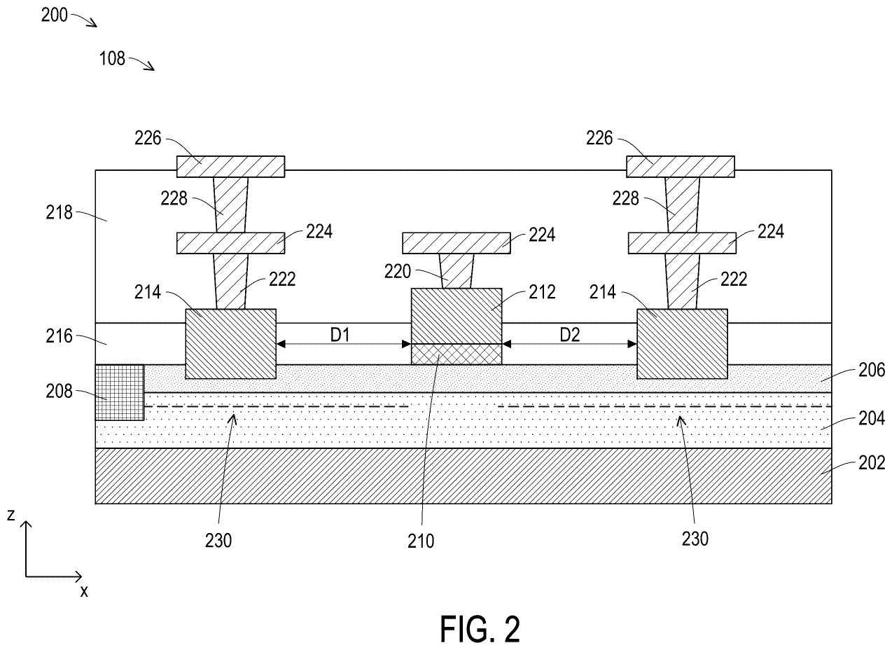

In some implementations, each capacitor 104 may include a HEMT-type capacitor. As discussed in more detail in connection with FIGS. 2, 5, and 6, a HEMT-type capacitor may include a similar arrangement of GaN-based layers to that of a HEMT. In addition, each HEMT-type capacitor may be a two-terminal capacitor, where a first terminal is a gate electrode, and a second terminal includes a first source/drain electrode connected to a second source/drain electrode.

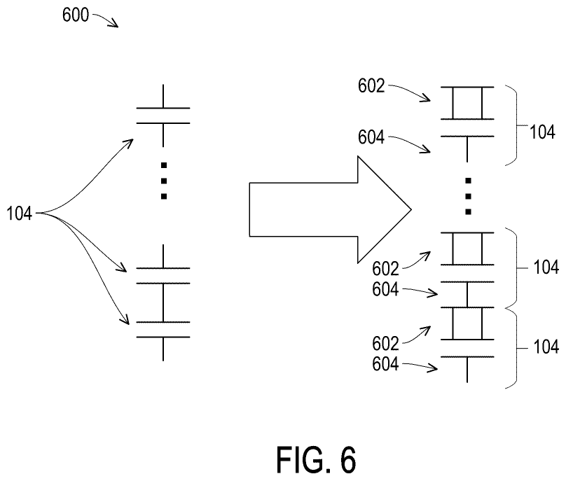

As discussed in more detail in connection with FIG. 6, in the stacked arrangement where the capacitors are HEMT-type capacitors, the first terminal of a HEMT-type capacitor in the stacked arrangement is connected to a second terminal of another HEMT-type capacitor in the stacked arrangement.

The resistor 106 may conduct large current surges during an ESD event, allowing the capacitors 104 to charge quickly and so that voltage may be clamped to a level to prevent damage to the high voltage HEMT 108 and/or a device circuit. The resistor 106 may limit current to control a rate at which the capacitors 104 charge during an ESD event. In some implementations, the resistive structure of the resistor 106 may include thick film materials, thin film materials, and/or metal-oxide materials. Some example materials for the resistive structure may include gallium nitride (GaN) in the case of a GaN-type resistor, titanium nitride (TiN), silicon chromium (SiCr), and/or silicon, among other materials.

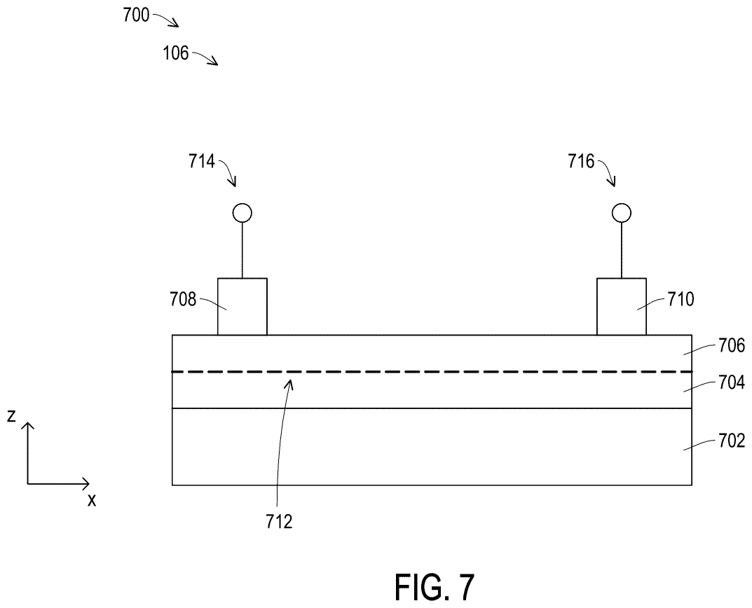

As discussed in more detail in connection with FIG. 7, a GaN-type resistor may include a similar arrangement of GaN-based layers to that of a HEMT. In addition, a GaN-type resistor may include a positive voltage terminal and a negative voltage terminal on a heterojunction layer (e.g., an aluminum gallium nitride (AlGaN) layer).

As indicated above, FIG. 1 is provided as an example. Other examples may differ from what is described with regard to FIG. 1.

FIG. 2 is a diagram of an example implementation 200 of a high voltage HEMT 108. As shown in FIG. 2, the high voltage HEMT 108 includes a substrate 202. The substrate 202 may correspond to a portion of a semiconductor wafer on which the semiconductor device 100 is formed. The substrate 202 includes a silicon (Si) substrate, a substrate formed of a material including silicon, a sapphire substrate, a silicon on insulator (SOI) substrate, or another type of semiconductor substrate. The substrate 202 may extend in an x-direction in the high voltage HEMT 108.

A first heterojunction layer 204 is formed on the substrate 202 in a z-direction in the high voltage HEMT 108. The first heterojunction layer 204 may be formed from undoped GaN, and may be epitaxially grown from a seed layer. A deposition tool may be used to deposit the material of the first heterojunction layer 204. The first heterojunction layer 204 may function as a carrier electron layer for the high voltage HEMT 108 (e.g., a GaN-based HEMT). The high voltage HEMT 108 may include a second heterojunction layer 206 that may include aluminum gallium nitride (AlGaN) and/or another suitable material. The second heterojunction layer 206 is formed on the first heterojunction layer 204 in a z-direction in the high voltage HEMT 108. The second heterojunction layer 206 may have a different bandgap than the first heterojunction layer 204, so that the first heterojunction layer 204 and the second heterojunction layer 206 may form a heterojunction structure for a gallium nitride-based HEMT. In some implementations, the first heterojunction layer 204 may include gallium arsenide (GaAs) and the second heterojunction layer 206 may include aluminum gallium arsenide (AlGaAs).

As further shown in FIG. 2, the high voltage HEMT 108 may include one or more isolation regions 208 (e.g., doped implant regions) formed in the second heterojunction layer 206 and the first heterojunction layer 204. In some implementations, an isolation region 208 is formed by an ion implantation process, and may be formed through the second heterojunction layer 206, and in a portion (e.g., upper portion) of the first heterojunction layer 204. Alternatively, in some implementations, an isolation region 208 may include a shallow trench isolation (STI) region. An STI region may include dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material.

Additionally, a gate electrode 212 (also referred to as a “gate”) may be formed over the heterojunction structure including the first heterojunction layer 204 and the second heterojunction layer 206 in the z-direction in the semiconductor device 100. A gate electrode 212 may be disposed on a gate separation layer 210 in the z-direction in the high voltage HEMT 108. The gate separation layer 210 is disposed between the gate electrode 212 and the second heterojunction layer 206. In some implementations, the gate separation layer 210 includes an insulator. Alternatively, the gate separation layer 210 includes a doped III-V material, such as p-doped gallium nitride (GaN). The doped material may pull electrons from the channel or may donate holes to the channel under the gate electrode 212 in order to form a broken channel as shown by the missing portion of the dotted line in FIG. 2 (e.g., when the gallium nitride-based electronic structure is a normally off or an enhancement mode (e-mode) III-V HEMT device). In some implementations, the gate separation layer 210 may be omitted, such as for a normally on or a depletion mode (d-mode) III-V HEMT device.

A gate electrode 212 may be disposed adjacent one or more source/drain electrodes 214. “Source/drain electrode” may refer to a source electrode or a drain electrode, individually or collectively, dependent upon the context. The source/drain electrodes 214 are disposed on the second heterojunction layer 206, with a portion of each source/drain electrode 214 disposed in the second heterojunction layer 206. Alternatively, the source/drain electrodes 214 are on a top surface of the second heterojunction layer 206, without being in the second heterojunction layer 206. The gate electrode 212 and the source/drain electrodes 214 may include one or more conductive materials (e.g., metals) such as titanium, aluminum, nickel, and/or gold, among other examples, or a polycrystalline material (e.g., polycrystalline silicon).

A dielectric layer 216 is disposed on the second heterojunction layer 206 and around sides of the gate separation layer 210, the gate electrode 212, and the source/drain electrodes 214. The dielectric layer 216 may include an oxide (e.g., a silicon oxide (SiOₓ) and/or another oxide material), and/or another suitable dielectric material. An inter-metal dielectric (IMD) layer 218 is formed on the dielectric layer 216. The IMD layer 218 may include an undoped silicate glass (USG), a boron-containing silicate glass (BSG), a fluorine-containing silicate glass (FSG), tetraethyl orthosilicate (TEOS), hydrogen silsesquioxane (HSQ), a silicon nitride (SiₓN_{y}), silicon carbide (SiC), silicon oxynitride (SiON), and/or another suitable dielectric material.

The IMD layer 218 may include a plurality of conductive structures such as, for example, a gate contact 220, source/drain contacts 222, first metallization structures 224, second metallization structures 226, and interconnect structures 228. One or more of the conductive structures are electrically coupled and/or physically coupled to the gate electrode 212 and/or source/drain electrodes 214. The conductive structures provide electrical routing that enables signals and/or power to be provided to and/or from the gate electrode 212 and/or source/drain electrodes 214. For example, the gate electrode 212 of the high voltage HEMT 108 may be electrically connected to the capacitors 104 and/or resistor through a gate contact 220 and one or more first metallization structures 224. A first source/drain electrode 214 of the high voltage HEMT 108 may be electrically connected to the supply voltage source 110 through a source/drain contact 222, one or more first metallization structures 224, one or more second metallization structures 226, and one or more interconnect structures 228. A second source/drain electrode 214 of the high voltage HEMT 108 may be electrically connected to the ground voltage source 112 through a source/drain contact 222, one or more first metallization structures 224, one or more second metallization structures 226, and one or more interconnect structures 228.

The conductive structures may include a combination of vias, trenches, contacts, plugs, interconnects, metallization layers, conductive traces, and/or other types of conductive structures. The conductive structures may be one or more electrically conductive materials such as tungsten (W), cobalt (Co), ruthenium (Ru), titanium (Ti), aluminum (Al), copper (Cu), aluminum copper (AlCu), gold (Au), nickel (Ni), and/or a combination thereof, among other examples of electrically conductive materials. In some implementations, one or more liner layers are included between the conductive structures and the IMD layers 218. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures may be arranged in a vertical manner (e.g., in the z-direction). The plurality of stacked conductive structures may be referred to as metallization layers (M-layers). For example, a metal-1 (M1) layer including first metallization structures 224 may be directly coupled to the gate contact 220 and/or the source/drain contacts 222, and a metal-2 (M2) layer may be located above the M1 layer in and/or on the IMD layer 218, a metal-2 (M2) layer including second metallization structures 226 may be located above the M1 layer, and so on. Additionally, via layers may be included between vertically arranged M-layers. For example, a via-1 (V1) layer including interconnect structures 228 may be included between the M1 layer and the M2 layer to interconnect the M1 layer and the M2 layer.

The portions of the first heterojunction layer 204 under the edges of the source/drain electrodes 214 and under portions of the second heterojunction layer 206 include two-dimensional electron gas (2DEG) channel regions 230. The 2DEG channel regions 230 are regions of high electron mobility between the first heterojunction layer 204 (e.g., GaN layer) and the second heterojunction layer 206 (e.g., AlGaN layer). In some implementations, the 2DEG channel regions 230 are adjacent to an interface between the first heterojunction layer 204 and the second heterojunction layer 206. The 2DEG channel regions 230 are not under the gate electrode 212 and the gate separation layer 210. In the case of GaN HEMTs, electrons generated in the second heterojunction layer 206 (e.g., AlGaN layer) move into the first heterojunction layer 204 (e.g., GaN layer) to form a depleted second heterojunction layer 206. This is due to a heterojunction created by different band-gap materials of the first heterojunction layer 204 and the second heterojunction layer 206, which forms a quantum well in a conduction band in the first heterojunction layer 204. The electrons in the conduction band are trapped and can move quickly without colliding with impurities in the first heterojunction layer 204 because the first heterojunction layer 204 is undoped. As a result, 2DEG channel regions 230 of an HEMT are created. The 2DEG channel regions 230 have a high concentration of highly mobile conducting electrons. The source/drain electrodes 214 are connected to (e.g., form an ohmic contact with) the 2DEG channel regions 230. In some implementations, the source/drain electrodes 214 are electrically connected to the 2DEG channel regions 230 even though the source/drain electrodes 214 are spaced apart from and are not in direct physical contact with the 2DEG channel regions 230.

In some implementations, in the case of a symmetric source/drain arrangement for the high voltage HEMT 108, an x-direction distance (e.g., spacing) between a gate structure (e.g., gate electrode 212 and/or gate separation layer 210) and an edge of a first source/drain electrode 214 (indicated in FIG. 2 as a dimension D1) is the same as an x-direction distance (e.g., spacing) between the gate structure (e.g., gate electrode 212 and/or gate separation layer 210) and an edge of a second source/drain electrode 214 (indicated in FIG. 2 as a dimension D2). In some implementations, in the case of an asymmetric source/drain arrangement for the high voltage HEMT 108, an x-direction distance D1 between the gate structure (e.g., gate electrode 212 and/or gate separation layer 210) and the edge of the first source/drain electrode 214 is different from (e.g., smaller than) an x-direction distance D2 between the gate structure (e.g., gate electrode 212 and/or gate separation layer 210) and the edge of the second source/drain electrode 214. A greater dimension D2 between the gate structure (e.g., gate electrode 212 and/or gate separation layer 210) and the second source/drain electrode 214, when the second source/drain electrode 214 is connected to the ground voltage source 112, may permit greater voltage dissipation than if the dimension D2 were equal to the dimension D1.

The high voltage HEMT 108 may include multiple fingers, where a “finger” includes a transistor structure including a gate electrode 212, and source/drain electrodes 214 adjacent to the gate electrode 212.

As indicated above, FIG. 2 is provided as an example. Other examples may differ from what is described with regard to FIG. 2.

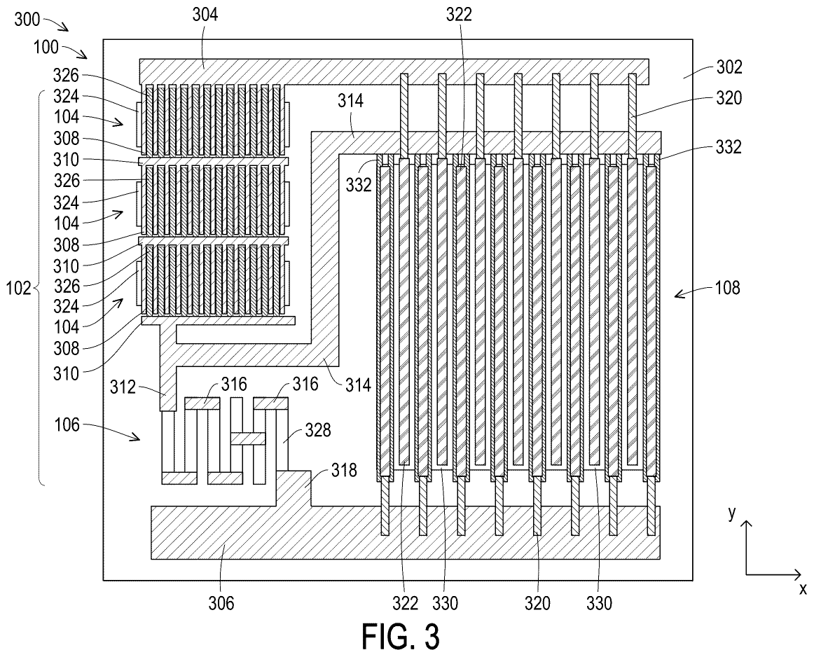

FIG. 3 is a diagram of an example implementation 300 of a layout of the semiconductor device 100. As shown in FIG. 3, the ESD protection circuit 102 is on a substrate 302. The substrate 302 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, sapphire, or another type of semiconductor material. The capacitors 104, the resistor 106, and the high voltage HEMT 108 may be formed on a substrate 302.

The semiconductor device 100 may include an interconnect layer including a plurality of conductive structures 304, 306, 308, 310, 312, 314, 316, 318, 320, and 322 (e.g., electrically conductive structures) formed in one or more dielectric layers on a substrate 302. The dielectric layers may include backend dielectric layers (e.g., interlayer dielectric (ILD) layers, intermetal dielectric (IMD) layers) and etch stop layers (ESLs) that are arranged in a direction that is approximately orthogonal to the substrate 302. The dielectric layers may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The conductive structures 304, 306, 308, 310, 312, 314, 316, 318, 320, and/or 322 are electrically coupled and/or physically coupled to the capacitors 104, resistor 106, and/or high voltage HEMT 108 of the ESD protection circuit 102, and/or other structures of the semiconductor device 100. Moreover, the conductive structures 304, 306, 308, 310, 312, 314, 316, 318, 320, and/or 322 may be electrically interconnected together in the interconnect layer. The conductive structures 304, 306, 308, 310, 312, 314, 316, 318, 320, and/or 322 correspond to circuit routing that enables signals and/or power to be provided to and/or from components of the ESD protection circuit 102. The conductive structures 304, 306, 308, 310, 312, 314, 316, 318, 320, and/or 322 may include a combination of conductive structures that extend primarily horizontally in the interconnect layer (e.g., trenches, conductive lines) and that are interconnected by interconnect structures (e.g., vias) that extend primarily vertically in the interconnect layer. The conductive structures 304, 306, 308, 310, 312, 314, 316, 318, 320, and/or 322 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer may be arranged in a vertical manner to facilitate electrical signals and/or power to be routed between integrated circuit devices in different layers. The conductive structures 304, 306, 308, 310, 312, 314, 316, 318, 320, and/or 322 may be arranged in alternating layers of metallization layers (referred to as “M”-layers) and via layers (referred to as “V”-layers). Each metallization layer may include one or more conductive structures laterally arranged in the interconnect layer, and each via layer may include one or more interconnect structures that interconnect the metallization layers in the interconnect layer. As an example, a metal-0 (M0) layer may be located at the bottom of the interconnect layer, a via-0 (V0) layer may be located above and coupled to the M0 layer in the interconnect layer, a metal-1 (M1) layer may be located above and coupled to the V0 layer in the interconnect layer, a via-1 (V1) layer may be located above and coupled to the M1 layer in the interconnect layer, a metal-2 (M2) layer may be located above and electrically coupled to the V1 layer in the interconnect layer, and so on.

For example, the conductive structures 304 and 306 may be part of a metallization layer (e.g., an M1 layer) and may respectively correspond to the supply voltage source 110 and the ground voltage source 112. The conductive structures 308 and 310 may be part of a metallization layer (e.g., an M1 layer) and may connect the capacitors 104 to each other and to the conductive structure 304 for the supply voltage source 110. The conductive structures 312 and 314 may be part of a metallization layer (e.g., an M1 layer) and may connect the capacitors 104 to the resistor 106 and to the gate of the high voltage HEMT 108, respectively. The conductive structures 316 may be part of a metallization layer (e.g., an M1 layer) and may connect portions of the resistor 106 to each other. The conductive structure 318 may be part of a metallization layer (e.g., an M1 layer) and may connect the resistor 106 to the ground voltage source 112 through the conductive structure 306. The conductive structures 320 may be part of a metallization layer (e.g., an M2 layer) and may connect the source/drain electrodes (e.g., source/drain electrodes 214) of the high voltage HEMT 108 to the supply voltage source 110 (through conductive structure 304) and the ground voltage source 112 (through conductive structure 306). The conductive structures 320 may be connected to the source/drain electrodes of the high voltage HEMT 108 through conductive structures 322. The conductive structures 322 may include a combination of metallization layers (e.g., an M1 layer and an M2 layer, and one or more via layers).

The capacitors 104 in the example implementation 300 may be HEMT-type capacitors, where source/drain electrodes are formed on an active region 324 of each HEMT-type capacitor. An “active region” includes, for example, source/drain regions and an area between the source/drain regions. In addition, gate structures 326 including, for example, gate electrodes and gate separation layers, may be formed on the active region 324 of each HEMT-type capacitor.

As shown in FIG. 3, there are three capacitors 104 (e.g., three HEMT-type capacitors) arranged in the y-direction. Although three capacitors 104 are shown, as noted herein, the quantity of capacitors 104 may be greater than three. The conductive structures 308 couple the source/drain electrodes of the HEMT-type capacitors to conductive structures 308 or 310. For example, the conductive structures 308 couple the source/drain electrodes of a first HEMT-type capacitor (e.g., uppermost capacitor 104 in the y-direction) to the conductive structure 304 corresponding to the supply voltage source 110. The gate structures 326 of the first HEMT-type capacitor are coupled to a conductive structure 310 between the first HEMT-type capacitor and second HEMT-type capacitor (e.g., middle capacitor 104 in the y-direction). The conductive structures 308 couple the source/drain electrodes of the second HEMT-type capacitor to the conductive structure 310 between the first HEMT-type capacitor and second HEMT-type capacitor. The gate structures 326 of the second HEMT-type capacitor are coupled to a conductive structure 310 between the second HEMT-type capacitor and third HEMT-type capacitor (e.g., lowermost capacitor 104 in the y-direction). The conductive structures 308 couple the source/drain electrodes of the third HEMT-type capacitor to the conductive structure 310 between the second HEMT-type capacitor and third HEMT-type capacitor. The gate structures 326 of the third HEMT-type capacitor are coupled to a conductive structure 310 under the third HEMT-type capacitor.

A conductive structure 312 couples the resistor 106 to the third conductive structure 310 under the third HEMT-type capacitor. The resistor 106 includes a resistive structure 328. The conductive structure 312 is coupled to a portion of the resistive structure 328, and portions of the resistive structure 328 are coupled to each other by conductive structures 316. The resistive structure 328 may include thick film materials, thin film materials, and/or metal-oxide materials. Some example materials for the resistive structure may include gallium nitride (GaN) in the case of a GaN-type resistor, titanium nitride (TiN), silicon chromium (SiCr), and/or silicon, among other materials. The resistive structure 328 is coupled to the conductive structure 306 corresponding to the ground voltage source 112 by the conductive structure 318.

The capacitors 104 and the resistor 106 are coupled to the high voltage HEMT 108 through the conductive structure 312 and the conductive structure 314, which extends from the conductive structure 312. Similar to the HEMT-type capacitors, the high voltage HEMT 108 includes an active region 330, which may include, for example, source/drain regions and an area between the source/drain regions. Source/drain electrodes of the high voltage HEMT 108 may be formed on the active region 330 of the high voltage HEMT 108. Gate structures 332 including, for example, gate electrodes and gate separation layers, may be formed on the active region 330 of the high voltage HEMT 108. The conductive structure 314 is coupled to the gate structures 332. The conductive structures 322 couple the source/drain electrodes of the high voltage HEMT 108 to the conductive structure 304 corresponding to the supply voltage source 110, and to the conductive structure 306 corresponding to the ground voltage source 112.

The conductive structures 308 and 322 extend over and/or on the active regions 324 and 330 to connect to source/drain regions. The conductive structures 310 and 320 respectively connect to gate structures 326 and 332.

As indicated above, FIG. 3 is provided as an example. Other examples may differ from what is described with regard to FIG. 3.

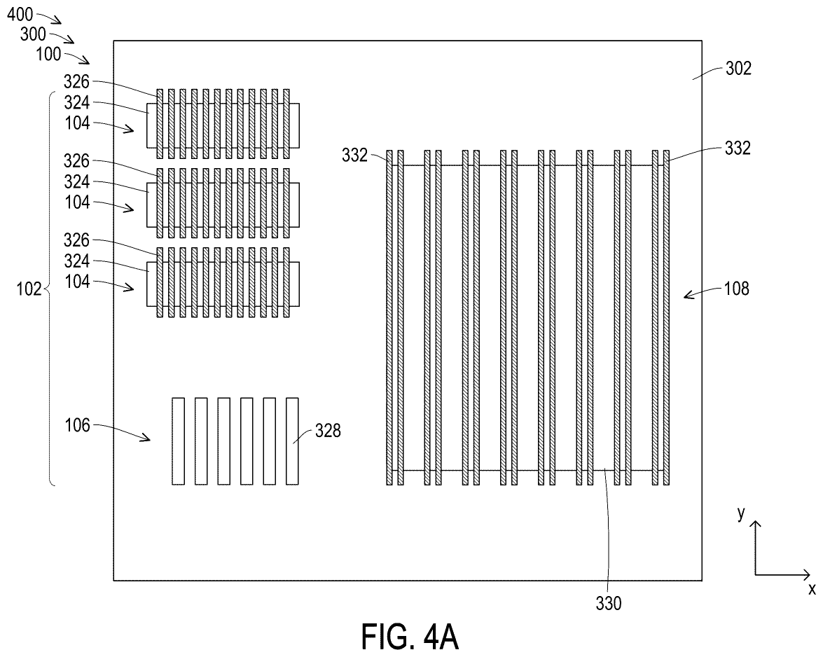

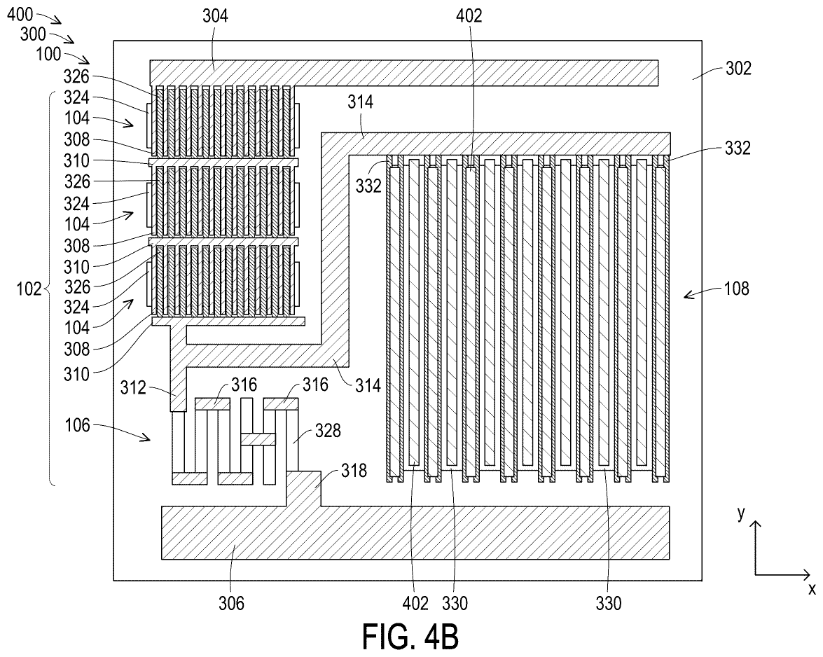

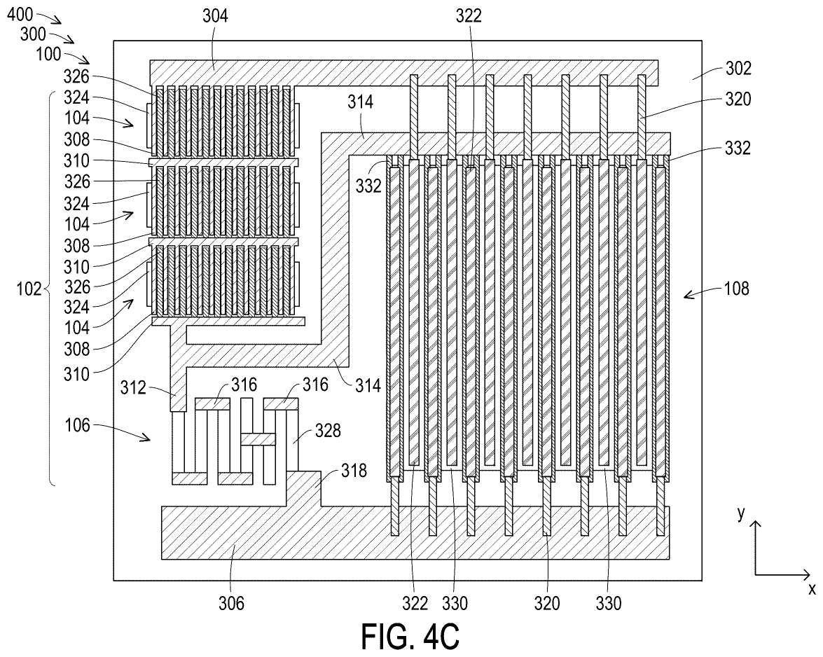

FIGS. 4A-4C are diagrams of an example implementation 400 of forming the semiconductor device 100 of the example implementation 300 described herein. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

Turning to FIG. 4A, substrate 302 may be provided. The substrate 302 may be provided as a semiconductor wafer, a semiconductor die, and/or another type of semiconductor substrate. In some implementations, the substrate 302 may be a doped substrate, such as a semiconductor substrate that is doped with one or more p-type dopants, a semiconductor substrate that is doped with one or more n-type dopants, and/or another type of doped substrate. In some implementations, the substrate 302 has a bulk resistivity (or volumetric resistivity) that is included in a range of approximately 1 ohm-centimeter to approximately 100 ohm-centimeters. However, other values for the range are within the scope of the present disclosure.

As further shown in FIG. 4A, the capacitors 104, the resistor 106, and the high voltage HEMT 108 are formed over and/or on the substrate 302. The resistive structure 328 of a resistor 106 may be formed in and/or on the substrate 302 of the semiconductor device 100. In some implementations, a deposition tool may be used to deposit the resistive structure 328 using a physical vapor deposition (PVD) technique, an atomic layer deposition (ALD) technique, a chemical vapor deposition (CVD) technique, an epitaxy technique, an oxidation technique, and/or another suitable deposition technique.

The active regions 324 and gate structures 326 of the capacitors 104 may be formed in and/or on the substrate 302 of the semiconductor device 100. In some implementations, a deposition tool may be used to deposit the active regions 324 and gate structures 326 using a PVD technique, an ALD technique, a CVD technique, an epitaxy technique, an oxidation technique, and/or another suitable deposition technique.

The active region 330 and gate structures 332 of the high voltage HEMT 108 may be formed in and/or on the substrate 302 of the semiconductor device 100. In some implementations, a deposition tool may be used to deposit the active region 330 and gate structures 332 using a PVD technique, an ALD technique, a CVD technique, an epitaxy technique, an oxidation technique, and/or another suitable deposition technique.

As shown in FIGS. 4B and 4C, an interconnect layer is formed on the substrate 302. The interconnect layer includes conductive structures 304-318 and 402 of a first metallization level (e.g., M1 level). The conductive structures 308 connect the uppermost capacitor 104 in the y-direction to the conductive structure 304 corresponding to the supply voltage source 110. The conductive structure 318 connects the resistor 106 to the conductive structure 306 corresponding to the ground voltage source 112. The conductive structures 308-316 interconnect the components (e.g., capacitors 104, resistor 106, and high voltage HEMT 108) of the ESD protection circuit 102 at a first metallization level (e.g., M1) and a first via level (e.g., V1) of the interconnect layer. The conductive structures 402 may be part of a first metallization level (e.g., M1) and may be connected to source/drain electrodes in the active region 330. Conductive structures of a second metallization level (e.g., M2) may be formed over the conductive structures 402.

As shown in FIG. 4C, the interconnect layer further includes conductive structures 320 and 322. The conductive structures 320 and 322 may be at a second metallization level (e.g., M2) and/or a second via level (e.g., V2) of the interconnect layer. The conductive structures 322 are formed over the conductive structures 402 and may be connected to the conductive structures 402 through one or more interconnect structures (e.g., vias). The conductive structures 320 connect the source/drain electrodes of the high voltage HEMT 108 to either the conductive structure 304 corresponding to the supply voltage source 110 or the conductive structure 306 corresponding to the ground voltage source 112.

One or more ILD layers and one or more ESLs of the interconnect layer may be formed above the substrate 302, over the active regions 324 and 330, over the gate structures 326 and 332, and over the resistive structure 328. The ILD layer(s) and the ESL(s) may be deposited in an alternating manner.

A deposition tool may be used to deposit an ILD layer using a PVD technique, an ALD technique, a CVD technique, an oxidation technique, and/or another suitable deposition technique. An ILD layer may be deposited in one or more deposition operations. In some implementations, a planarization tool may be used to perform a planarization operation (e.g., a chemical mechanical planarization (CMP) operation) to planarize an ILD layer after the ILD layer is deposited.

A deposition tool may be used to deposit an ESL using a PVD technique, an ALD technique, a CVD technique, an oxidation technique, and/or another suitable deposition technique. An ESL may be deposited in one or more deposition operations. In some implementations, a planarization tool may be used to perform a planarization operation (e.g., a CMP operation) to planarize an ESL after the ESL is deposited.

Recesses may be formed through the ILD layer(s) and the ESL(s). The recesses may be formed over the active regions 324 and 330, over the gate structures 326 and 332, and over the resistive structure 328.

In some implementations, a pattern in a photoresist layer is used to etch the ILD layer(s) and the ESL(s) to form the recesses. In these implementations, a deposition tool may be used to form the photoresist layer on the topmost ILD layer. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) and the ESL(s) based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

Conductive structures 308-322 and 402 may be formed in the recesses to form, for example, source/drain contacts on the source/drain electrodes (e.g., source/drain electrodes 214), gate contacts on the gate structures 326 and 332, and resistor contacts on the resistive structure 328.

A deposition tool may be used to deposit the source/drain contacts, gate contacts, and resistor contacts using a CVD technique, a PVD technique, an ALD technique, an electroplating technique, and/or another suitable deposition technique. The source/drain contacts, gate contacts, capacitor contacts, and resistor contacts may be deposited in one or more deposition operations. In some implementations, a seed layer is first deposited, and a source/drain contact, gate contact, capacitor contact, and/or resistor contact is deposited on the seed layer. In some implementations, a liner (e.g., an adhesion liner, a barrier liner) is first deposited, and a source/drain contact, gate contact, capacitor contact, and/or resistor contact is deposited on the liner. In some implementations, a planarization tool is used to perform a planarization operation (e.g., a CMP operation) to planarize the source/drain contacts, gate contacts, and resistor contacts after the source/drain contacts, gate contacts, and resistor contacts are deposited.

As indicated above, FIGS. 4A-4C are provided as examples. Other examples may differ from what is described with regard to FIGS. 4A-4C.

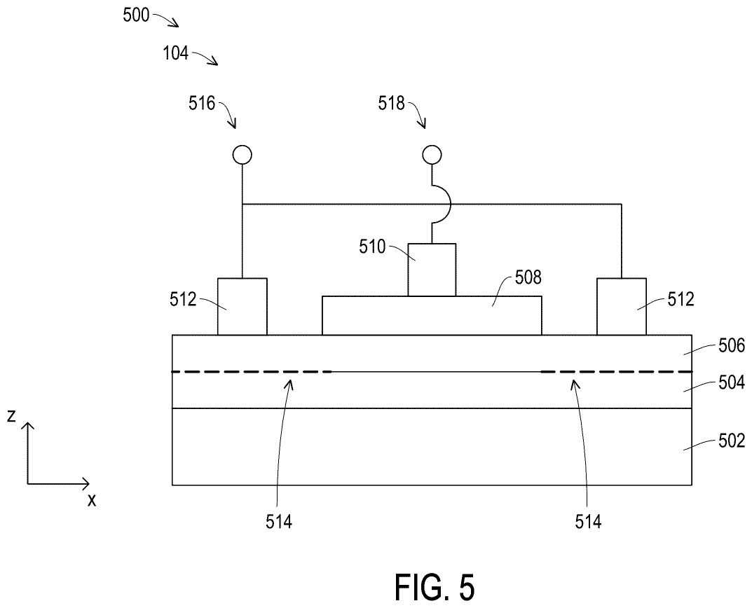

FIG. 5 is a diagram of an example implementation 500 of a capacitor 104, where the capacitor 104 is a HEMT-type capacitor. The structure of the HEMT-type capacitor is similar to the structure of the high voltage HEMT 108 described in connection with FIG. 2. As shown in FIG. 5, the capacitor 104 (e.g., HEMT-type capacitor) includes a substrate 502. The substrate 502 may correspond to a portion of a semiconductor wafer on which the semiconductor device 100 is formed. The substrate 502 includes a silicon (Si) substrate, a substrate formed of a material including silicon, a sapphire substrate, a silicon on insulator (SOI) substrate, or another type of semiconductor substrate. The substrate 502 may extend in an x-direction in the capacitor 104.

A first heterojunction layer 504 is formed on the substrate 502 in a z-direction in the capacitor 104. The first heterojunction layer 504 may be formed from undoped GaN, and may be epitaxially grown from a seed layer. A deposition tool may be used to deposit the material of the first heterojunction layer 504. The first heterojunction layer 504 may function as a carrier electron layer for the capacitor 104 (e.g., a GaN-based HEMT capacitor). The capacitor 104 may include a second heterojunction layer 506 that may include aluminum gallium nitride (AlGaN) and/or another suitable material. The second heterojunction layer 506 is formed on the first heterojunction layer 504 in a z-direction in the capacitor 104. The second heterojunction layer 506 may have a different bandgap than the first heterojunction layer 504, so that the first heterojunction layer 504 and the second heterojunction layer 506 may form a heterojunction structure for a HEMT-type capacitor. In some implementations, the first heterojunction layer 504 may include gallium arsenide (GaAs) and the second heterojunction layer 506 may include aluminum gallium arsenide (AlGaAs).

As further shown in FIG. 5, a gate electrode 510 (also referred to as a “gate”) may be formed over the heterojunction structure including the first heterojunction layer 504 and the second heterojunction layer 506 in the z-direction in the semiconductor device 100. A gate electrode 510 may be disposed on a gate separation layer 508 in the z-direction in the capacitor 104. The gate separation layer 508 is disposed between the gate electrode 510 and the second heterojunction layer 506. In some implementations, the gate separation layer 508 includes an insulator. Alternatively, the gate separation layer 508 includes a doped III-V material, such as p-doped gallium nitride (GaN). The doped material may pull electrons from the channel or may donate holes to the channel under the gate electrode 510 in order to form a broken channel as shown by the missing portion of the dotted line in FIG. 5.

A gate electrode 510 may be disposed between two source/drain electrodes 512. The source/drain electrodes 512 are disposed on the second heterojunction layer 506. Alternatively, a portion of each source/drain electrode 512 may be disposed in the second heterojunction layer 506. The gate electrode 510 and the source/drain electrodes 512 may include one or more conductive materials (e.g., metals) such as titanium, aluminum, nickel, and/or gold, among other examples, or a polycrystalline material (e.g., polycrystalline silicon).

The portions of the first heterojunction layer 504 under the edges of the source/drain electrodes 512 and under portions of the second heterojunction layer 506 include 2DEG channel regions 514. The 2DEG channel regions 514 are regions of high electron mobility between the first heterojunction layer 504 (e.g., GaN layer) and the second heterojunction layer 506 (e.g., AlGaN layer). In some implementations, the 2DEG channel regions 514 are at or adjacent to an interface between the first heterojunction layer 504 and the second heterojunction layer 506. The 2DEG channel regions 514 are not under the gate electrode 510 and the gate separation layer 508. In the case of GaN HEMT-type capacitors, electrons generated in the second heterojunction layer 506 (e.g., AlGaN layer) move into the first heterojunction layer 504 (e.g., GaN layer) to form a depleted second heterojunction layer 506. This is due to a heterojunction created by different band-gap materials of the first heterojunction layer 504 and the second heterojunction layer 506, which forms a quantum well in a conduction band in the first heterojunction layer 504. The electrons in the conduction band are trapped and can move quickly without colliding with impurities in the first heterojunction layer 504 because the first heterojunction layer 504 is undoped. As a result, 2DEG channel regions 514 of an HEMT-type capacitor are created. The 2DEG channel regions 514 have a high concentration of highly mobile conducting electrons. The source/drain electrodes 512 are connected to (e.g., form an ohmic contact with) the 2DEG channel regions 514. In some implementations, the source/drain electrodes 512 are electrically connected to the 2DEG channel regions 514 even though the source/drain electrodes 512 are spaced apart from and are not in direct physical contact with the 2DEG channel regions 514.

As shown in FIG. 5, the capacitor 104 (e.g., HEMT-type capacitor) is a two-terminal capacitor, where a first terminal is the gate electrode 510 connected to a voltage source 518, and a second terminal includes a first source/drain electrode 512 connected to a second source/drain electrode 512, where the first source/drain electrode 512 and the second source/drain electrode 512 are commonly connected to a voltage source 516.

As indicated above, FIG. 5 is provided as an example. Other examples may differ from what is described with regard to FIG. 5.

FIG. 6 is a diagram of an example implementation 600 of a stacked capacitor arrangement described herein. In a stacked arrangement where the capacitors are HEMT-type capacitors, each capacitor 104 includes a terminal 602 with two source/drain electrodes connected to each other, and a terminal 604 including a gate electrode. In the stacked arrangement, the connection between two capacitors 104 in the stack is established by the terminal 602 of one HEMT-type capacitor being connected to a terminal 604 of another HEMT-type capacitor in the stacked arrangement. In this way, a plurality of capacitors 104 (e.g., HEMT-type capacitors) are connected to each other in series in a stacked arrangement. Referring back to FIG. 3, the connection between the terminals 602 and 604 may be provided through a conductive structure 310 between two capacitors 104, where the conductive structure 310 is connected to gate structures 326 of one capacitor 104 and to the active region 324 (including source/drain electrodes) of another capacitor 104 through the conductive structures 308.

As indicated above, FIG. 6 is provided as an example. Other examples may differ from what is described with regard to FIG. 6.

FIG. 7 is a diagram of an example implementation 700 of a resistor 106, where the resistor 106 is a GaN-type resistor. The structure of the GaN-type resistor is similar to the structure of the high voltage HEMT 108 described in connection with FIG. 2 and/or the structure of the HEMT-type capacitor described in connection with FIG. 5. As shown in FIG. 7, the resistor 106 (e.g., GaN-type resistor) includes a substrate 702. The substrate 702 may correspond to a portion of a semiconductor wafer on which the semiconductor device 100 is formed. The substrate 702 includes a silicon (Si) substrate, a substrate formed of a material including silicon, a sapphire substrate, a silicon on insulator (SOI) substrate, or another type of semiconductor substrate. The substrate 702 may extend in an x-direction in the resistor 106.

A first heterojunction layer 704 is formed on the substrate 702 in a z-direction in the resistor 106. The first heterojunction layer 704 may be formed from undoped GaN, and may be epitaxially grown from a seed layer. A deposition tool may be used to deposit the material of the first heterojunction layer 704. The first heterojunction layer 704 may function as a carrier electron layer for the resistor 106 (e.g., a GaN-based resistor). The resistor 106 may include a second heterojunction layer 706 that may include aluminum gallium nitride (AlGaN) and/or another suitable material. The second heterojunction layer 706 is formed on the first heterojunction layer 704 in a z-direction in the resistor 106. The second heterojunction layer 706 may have a different bandgap than the first heterojunction layer 704, so that the first heterojunction layer 704 and the second heterojunction layer 706 may form a heterojunction structure for a GaN-type resistor. In some implementations, in the case of a GaAs-type resistor, the first heterojunction layer 704 may include gallium arsenide (GaAs) and the second heterojunction layer 706 may include aluminum gallium arsenide (AlGaAs).

As further shown in FIG. 7, a first (e.g., positive) terminal 708 and a second (e.g., negative) terminal 710 may be formed over the heterojunction structure including the first heterojunction layer 704 and the second heterojunction layer 706 in the z-direction in the semiconductor device 100. The first terminal 708 and the second terminal 710 may include one or more conductive materials (e.g., metals) such as titanium, aluminum, nickel, and/or gold, among other examples, or a polycrystalline material (e.g., polycrystalline silicon).

A 2DEG channel region 712 is located between the first heterojunction layer 704 and the second heterojunction layer 706. The 2DEG channel region 712 is a region of high electron mobility between the first heterojunction layer 704 (e.g., GaN layer) and the second heterojunction layer 706 (e.g., AlGaN layer). In some implementations, the 2DEG channel region 712 is at or adjacent to an interface between the first heterojunction layer 704 and the second heterojunction layer 706. In the case of GaN-type resistor, electrons generated in the second heterojunction layer 706 (e.g., AlGaN layer) move into the first heterojunction layer 704 (e.g., GaN layer) to form a depleted second heterojunction layer 706. This is due to a heterojunction created by different band-gap materials of the first heterojunction layer 704 and the second heterojunction layer 706, which forms a quantum well in a conduction band in the first heterojunction layer 704. The electrons in the conduction band are trapped and can move quickly without colliding with impurities in the first heterojunction layer 704 because the first heterojunction layer 704 is undoped. As a result, a 2DEG channel region 712of a GaN-type resistor is created. The 2DEG channel region 712 has a high concentration of highly mobile conducting electrons. The first terminal 708 and the second terminal 710 are connected to (e.g., form an ohmic contact with) the 2DEG channel region 712. In some implementations, the first terminal 708 and the second terminal 710 are electrically connected to the 2DEG channel region 712 even though the first terminal 708 and the second terminal 710 are spaced apart from and are not in direct physical contact with the 2DEG channel region 712.

As shown in FIG. 7, the first (e.g., positive) terminal 708 is connected to a voltage source 714, and the second (e.g., negative) terminal 710 is connected to a voltage source 716.

As indicated above, FIG. 7 is provided as an example. Other examples may differ from what is described with regard to FIG. 7.

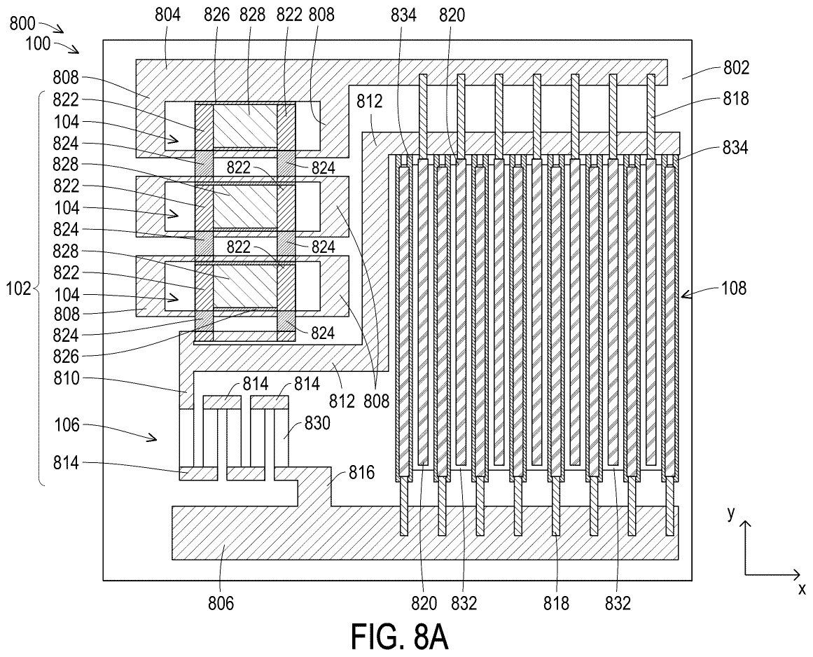

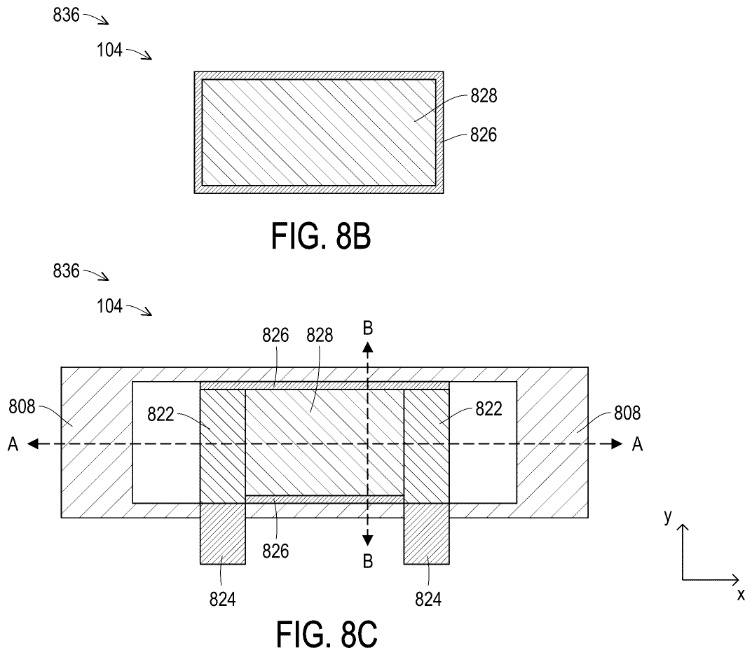

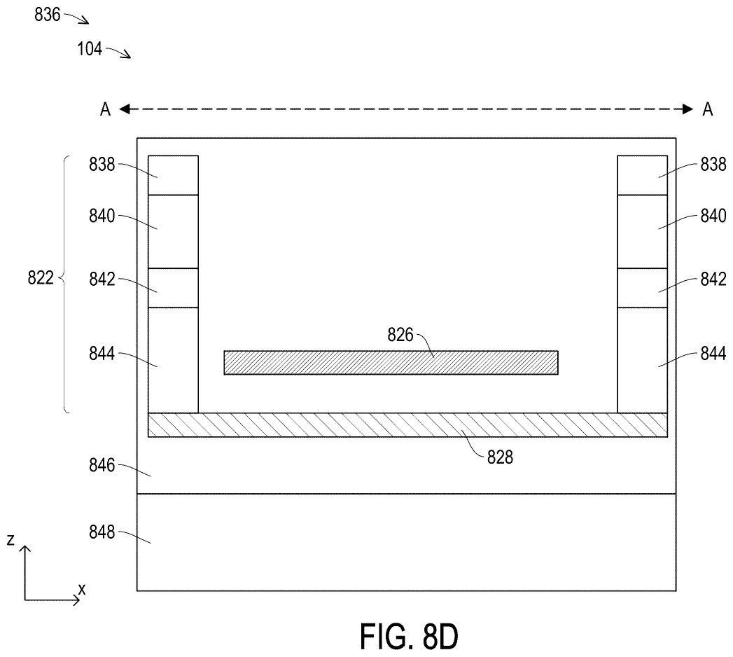

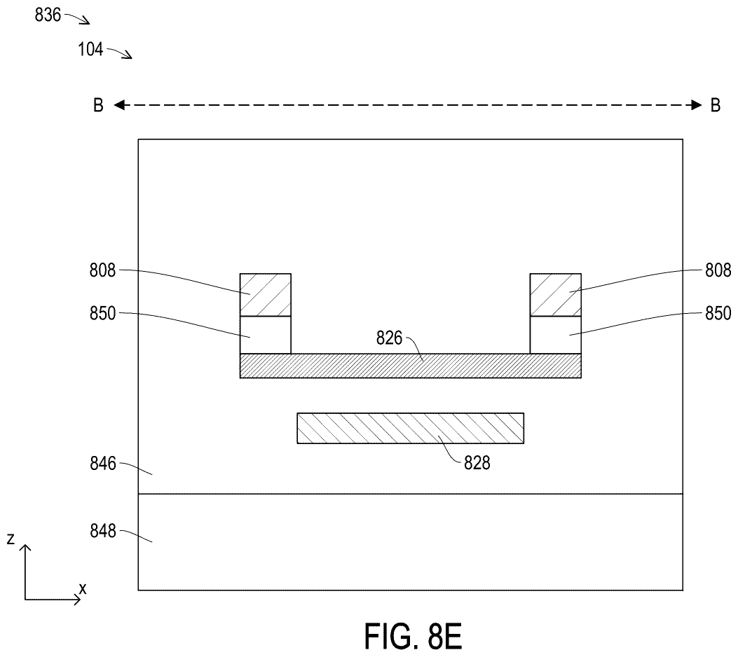

FIG. 8A is a diagram of an example implementation 800 of a layout of the semiconductor device 100. The layout in the example implementation 800 is similar to the layout in the example implementation 300 described in connection with FIG. 3. As shown in FIG. 8A, the ESD protection circuit 102 is on a substrate 802. The substrate 802 may include silicon (Si) (e.g., a silicon substrate), a silicon layer or another type of semiconductor layer, a material including silicon, a III-V compound semiconductor material such as gallium arsenide (GaAs), a silicon on insulator (SOI) substrate, sapphire, or another type of semiconductor material. The capacitors 104, the resistor 106, and the high voltage HEMT 108 may be formed on a substrate 802.

The semiconductor device 100 may include an interconnect layer including a plurality of conductive structures 804, 806, 808, 810, 812, 814, 816, 818, 820, 822, and 824 (e.g., electrically conductive structures) formed in one or more dielectric layers on a substrate 802. The dielectric layers may include backend dielectric layers (e.g., interlayer dielectric (ILD) layers, intermetal dielectric (IMD) layers) and etch stop layers (ESLs) that are arranged in a direction that is approximately orthogonal to the substrate 802. The dielectric layers may each include various dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The conductive structures 804, 806, 808, 810, 812, 814, 816, 818, 820, 822, and/or 824 are electrically coupled and/or physically coupled to the capacitors 104, resistor 106, and/or high voltage HEMT 108 of the ESD protection circuit 102, and/or other structures of the semiconductor device 100. Moreover, the conductive structures 804, 806, 808, 810, 812, 814, 816, 818, 820, 822, and/or 824 may be electrically interconnected together in the interconnect layer. The conductive structures 804, 806, 808, 810, 812, 814, 816, 818, 820, 822, and/or 824 correspond to circuit routing that enables signals and/or power to be provided to and/or from components of the ESD protection circuit 102. The conductive structures 804, 806, 808, 810, 812, 814, 816, 818, 820, 822, and/or 824 may include a combination of conductive structures that extend primarily horizontally in the interconnect layer (e.g., trenches, conductive lines) and that are interconnected by interconnect structures (e.g., vias) that extend primarily vertically in the interconnect layer. The conductive structures 804, 806, 808, 810, 812, 814, 816, 818, 820, 822, and/or 824 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer may be arranged in a vertical manner to facilitate electrical signals and/or power to be routed between integrated circuit devices in different layers. The conductive structures 804, 806, 808, 810, 812, 814, 816, 818, 820, 822, and/or 824 may be arranged in alternating layers of metallization layers (referred to as “M”-layers) and via layers (referred to as “V”-layers). Each metallization layer may include one or more conductive structures laterally arranged in the interconnect layer, and each via layer may include one or more interconnect structures that interconnect the metallization layers in the interconnect layer. As an example, a metal-0 (M0) layer may be located at the bottom of the interconnect layer, a via-0 (V0) layer may be located above and coupled to the M0 layer in the interconnect layer, a metal-1 (M1) layer may be located above and coupled to the V0 layer in the interconnect layer, a via-1 (V1) layer may be located above and coupled to the M1 layer in the interconnect layer, a metal-2 (M2) layer may be located above and electrically coupled to the V1 layer in the interconnect layer, and so on.

For example, the conductive structures 804 and 806 may be part of a metallization layer (e.g., an M1 layer) and may respectively correspond to the supply voltage source 110 and the ground voltage source 112. The conductive structures 808 may be part of a metallization layer (e.g., an M1 layer). The conductive structures 822 may be in multiple metallization layers (e.g., M1 and M2 layers) and may include interconnect structures in one or more via layers (e.g., V1 and V2 layers). The conductive structures 824 may be part of a metallization layer (e.g., an M2 layer). The conductive structures 808, 822, and 824 may connect the capacitors 104 to each other and to the conductive structure 804 for the supply voltage source 110. The conductive structures 810 and 812 may be part of a metallization layer (e.g., an M1 layer) and may connect the capacitors 104 to the resistor 106 and to the gate of the high voltage HEMT 108, respectively. The conductive structures 814 may be part of a metallization layer (e.g., an M1 layer) and may connect portions of the resistor 106 to each other. The conductive structure 816 may be part of a metallization layer (e.g., an M1 layer) and may connect the resistor 106 to the ground voltage source 112 through the conductive structure 806. The conductive structures 818 may be part of a metallization layer (e.g., an M2 layer) and may connect the source/drain electrodes (e.g., source/drain electrodes 214) of the high voltage HEMT 108 to the supply voltage source 110 (through conductive structure 804) and the ground voltage source 112 (through conductive structure 806). The conductive structures 818 may be connected to the source/drain electrodes of the high voltage HEMT 108 through conductive structures 820. The conductive structures 820 may include a combination of metallization layers (e.g., an M1 layer and an M2 layer, and one or more via layers).

Referring to the example implementation 836 of a capacitor 104 shown in FIGS. 8B and 8C, the capacitors 104 in the example implementation 800 may be MIM capacitors, including bottom electrode layers 826 and top electrode layers 828 arranged in an alternating manner and separated by one or more insulator layers. For example, the insulator layers may include an insulator layer stack of zirconium oxide (ZrOₓ such as ZrO₂) and aluminum oxide (AlₓO_{y} such as Al₂O₃), such as a ZrO₂/Al₂O₃/ZrO₂ (ZAZ) dielectric layer stack. The bottom electrode layers 826 and top electrode layers 828 may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples.

As shown in FIG. 8A, there are three capacitors 104 (e.g., three MIM capacitors) arranged in the y-direction. Although three capacitors 104 are shown, as noted herein, the quantity of capacitors 104 may be greater than three. As shown in FIGS. 8A and 8C, the conductive structures 808 are coupled to the bottom electrode layers 826 and top and bottom portions of the capacitors 104 in the y-direction. The conductive structures 822 are coupled to the top electrode layers 828 at lateral side portions of the capacitors 104 in the x-direction.

In some implementations, the conductive structures 822 connected to the top electrode layers 828 include a combination of metallization structures and interconnect structures. For example, referring to FIG. 8D, the conductive structures 822 include conductive structures 838 (e.g., metallization structures) in a second metallization level (e.g., M2), conductive structures 840 (e.g., interconnect structures) in a second via level (e.g., V2), conductive structures 842 (e.g., metallization structures) in a first metallization level (e.g., M1), and conductive structures 844 (e.g., interconnect structures) in a first via level (e.g., V1) of the interconnect layer. The conductive structures 838, 840, 842, and 844, and the top and bottom electrode layers 828 and 826, may be formed in an IMD layer 846, which is formed on a gallium nitride (GaN) layer 848.

As shown in FIG. 8E, the conductive structures 808, which may be metallization structures in a first metallization level (e.g., M1), may be connected to the bottom electrode layer 826 through conductive structures 850 (e.g., interconnect structures) in a first via level (e.g., V1).

In some implementations, the conductive structures 808 couple the bottom electrode layer 826 of a first MIM capacitor (e.g., uppermost capacitor 104 in the y-direction) to the conductive structure 804 corresponding to the supply voltage source 110. The top electrode layer 828 of the first MIM capacitor is coupled to the conductive structures 822 and to conductive structures 824 between the first MIM capacitor and second MIM capacitor (e.g., middle capacitor 104 in the y-direction). The conductive structures 822 and 824 couple the top electrode layer 828 of the first MIM capacitor to the bottom electrode layer 826 of the second MIM capacitor. The top electrode layer 828 of the second MIM capacitor is coupled to the conductive structures 822 and to conductive structures 824 between the second MIM capacitor and third MIM capacitor (e.g., lowermost capacitor 104 in the y-direction). The conductive structures 822 and 824 couple the top electrode layer 828 of the second MIM capacitor to the bottom electrode layer 826 of the third MIM capacitor. For example, the top electrode layer 828 of MIM capacitor in a stacked arrangement of capacitors 104 may be coupled to a bottom electrode layer 826 of another MIM capacitor in the stacked arrangement of capacitors 104 using conductive structures 838, 840, 842, and 844 above the top electrode layer 828, conductive structure 824 between the MIM capacitors, and conductive structures 808 and 850 above the bottom electrode layer 826.

A conductive structure 810 couples the resistor 106 to the conductive structures 822 and 824 under the third MIM capacitor. The resistor 106 includes a resistive structure 830. The conductive structure 810 is coupled to a portion of the resistive structure 830, and portions of the resistive structure 830 are coupled to each other by conductive structures 814. The resistive structure 830 may include thick film materials, thin film materials, and/or metal-oxide materials. Some example materials for the resistive structure may include gallium nitride (GaN) in the case of a GaN-type resistor, titanium nitride (TiN), silicon chromium (SiCr), and/or silicon, among other materials. The resistive structure 830 is coupled to the conductive structure 806 corresponding to the ground voltage source 112 by the conductive structure 816.

The capacitors 104 and the resistor 106 are coupled to the high voltage HEMT 108 through the conductive structure 810 and the conductive structure 812, which extends from the conductive structure 810. The high voltage HEMT 108 in the example implementation 800 includes an active region 832, which may include, for example, source/drain regions and an area between the source/drain regions. Source/drain electrodes of the high voltage HEMT 108 may be formed on the active region 832 of the high voltage HEMT 108. Gate structures 834 including, for example, gate electrodes and gate separation layers, may be formed on the active region 832 of the high voltage HEMT 108. The conductive structure 812 is coupled to the gate structures 834. The conductive structures 820 couple the source/drain electrodes of the high voltage HEMT 108 to the conductive structure 804 corresponding to the supply voltage source 110, and to the conductive structure 806 corresponding to the ground voltage source 112.

The conductive structures 820 extend over and/or on the active region 832 to connect to source/drain regions. The conductive structure 812 connects to the gate structures 834.

As indicated above, FIGS. 8A-8E are provided as examples. Other examples may differ from what is described with regard to FIGS. 8A-8E.

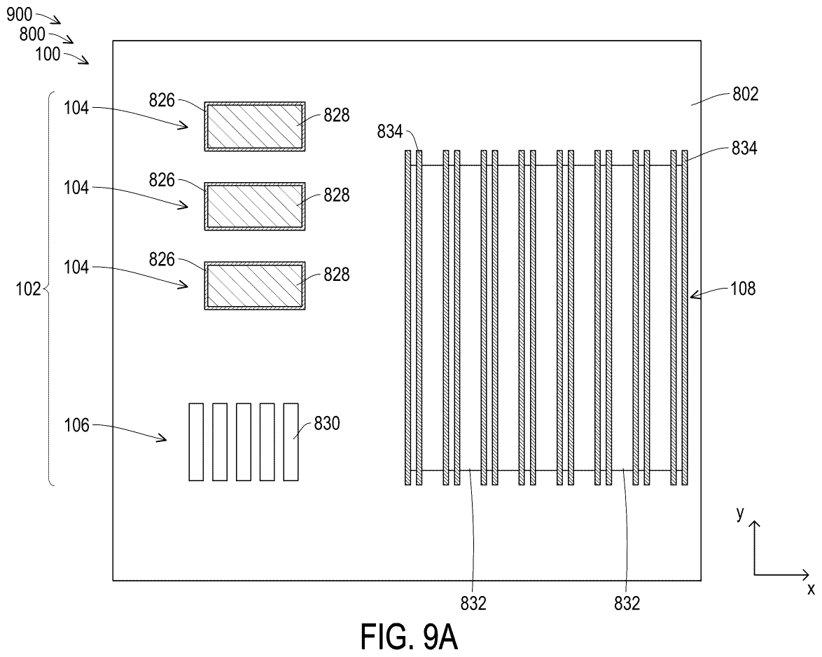

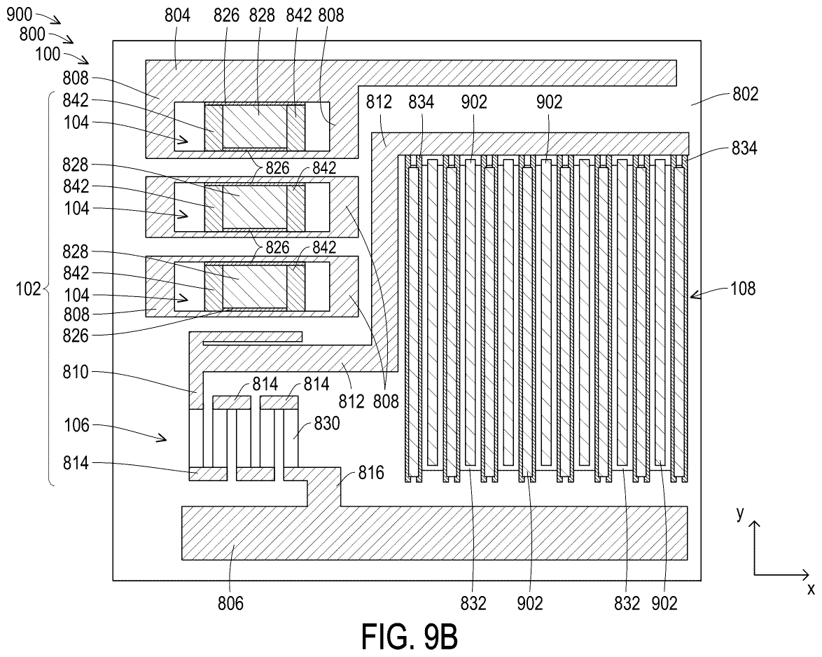

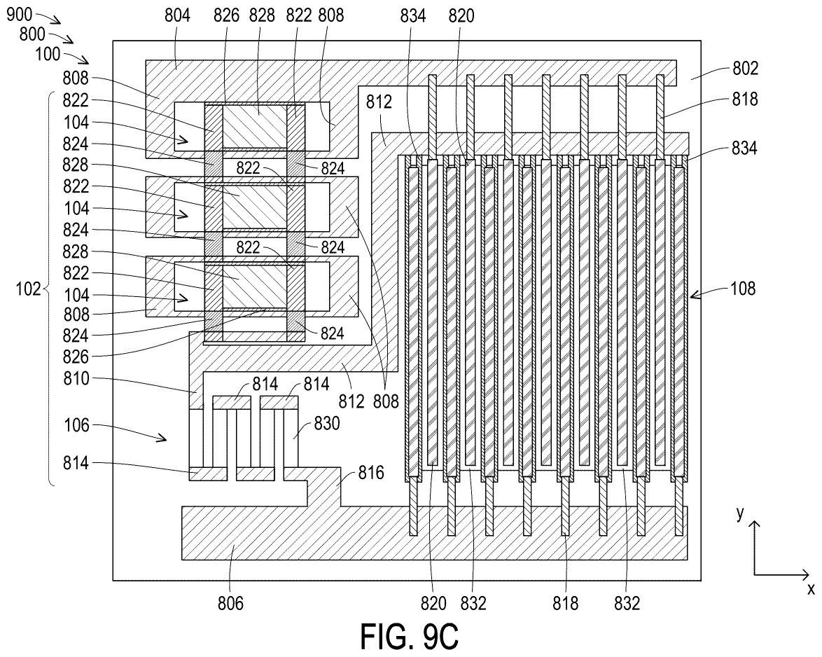

FIGS. 9A-9C are diagrams of an example implementation 900 of forming the semiconductor device 100 of the example implementation 800 described herein. In some implementations, one or more semiconductor processing tools may be used to perform one or more of the operations described in connection with the example implementation 900, such as a deposition tool, an exposure tool, a developer tool, an etch tool, a planarization tool, a plating tool, and/or another type of semiconductor processing tool.

Turning to FIG. 9A, substrate 802 may be provided. The substrate 802 may be provided as a semiconductor wafer, a semiconductor die, and/or another type of semiconductor substrate. In some implementations, the substrate 802 may be a doped substrate, such as a semiconductor substrate that is doped with one or more p-type dopants, a semiconductor substrate that is doped with one or more n-type dopants, and/or another type of doped substrate. In some implementations, the substrate 802 has a bulk resistivity (or volumetric resistivity) that is included in a range of approximately 1 ohm-centimeter to approximately 100 ohm-centimeters. However, other values for the range are within the scope of the present disclosure.

As further shown in FIG. 9A, the capacitors 104, the resistor 106, and the high voltage HEMT 108 are formed over and/or on the substrate 802. The resistive structure 830 of a resistor 106 may be formed in and/or on the substrate 802 of the semiconductor device 100. In some implementations, a deposition tool may be used to deposit the resistive structure 830 using a physical vapor deposition (PVD) technique, an atomic layer deposition (ALD) technique, a chemical vapor deposition (CVD) technique, an epitaxy technique, an oxidation technique, and/or another suitable deposition technique.

The capacitors 104 (e.g., MIM capacitors), including the bottom electrode layers 826, the one or more insulator layers deposited on the bottom electrode layers 826, and the top electrode layers 828 deposited on the one or more insulator layers, may be formed in and/or on the substrate 802 of the semiconductor device 100. In some implementations, a deposition tool may be used to deposit the bottom electrode layers 826, the one or more insulator layers on the bottom electrode layers 826, and the top electrode layers 828 on the one or more insulator layers using a PVD technique, an ALD technique, a CVD technique, an epitaxy technique, an oxidation technique, and/or another suitable deposition technique.

The active region 832 and gate structures 834 of the high voltage HEMT 108 may be formed in and/or on the substrate 802 of the semiconductor device 100. In some implementations, a deposition tool may be used to deposit the active region 832 and gate structures 834 using a PVD technique, an ALD technique, a CVD technique, an epitaxy technique, an oxidation technique, and/or another suitable deposition technique.

As shown in FIGS. 9B and 9C, an interconnect layer is formed on the substrate 802. The interconnect layer includes conductive structures 804-816, 842 and 902 of a first metallization level (e.g., M1 level). Some of the conductive structures 808 connect the uppermost capacitor 104 in the y-direction to the conductive structure 804 corresponding to the supply voltage source 110. The conductive structure 816 connects the resistor 106 to the conductive structure 806 corresponding to the ground voltage source 112. The conductive structures 808-814 interconnect the components (e.g., capacitors 104, resistor 106, and high voltage HEMT 108) of the ESD protection circuit 102 at a first metallization level (e.g., M1) and a first via level (e.g., V1) of the interconnect layer. The conductive structures 842 and 902 may be part of a first metallization level (e.g., M1). The conductive structures 842 may be connected to the top electrode layers 828 at lateral side portions of the capacitors 104 in the x-direction. The conductive structures 902 may be connected to source/drain electrodes in the active region 832. Conductive structures of a second metallization level (e.g., M2) and/or one or more via levels (e.g., V1, V2) may be formed over the conductive structures 842 and 902.

As shown in FIG. 9C, the interconnect layer further includes conductive structures 818-824. The conductive structures 818-824 may be at a second metallization level (e.g., M2) and/or one or more via levels (e.g., V1, V2) of the interconnect layer. As shown in FIG. 8D, the conductive structures 822 may include the conductive structures 838, 840, 842, and 844. The conductive structures 820 are formed over the conductive structures 902 and may be connected to the conductive structures 902 through one or more interconnect structures (e.g., vias). The conductive structures 818 connect the source/drain electrodes of the high voltage HEMT 108 to either the conductive structure 804 corresponding to the supply voltage source 110 or the conductive structure 806 corresponding to the ground voltage source 112.

One or more ILD layers and one or more ESLs of the interconnect layer may be formed above the substrate 802, over the bottom electrode layers 826, over the top electrode layers 828, over the active region 832, over the gate structures 834, and over the resistive structure 830. The ILD layer(s) and the ESL(s) may be deposited in an alternating manner.

A deposition tool may be used to deposit an ILD layer using a PVD technique, an ALD technique, a CVD technique, an oxidation technique, and/or another suitable deposition technique. An ILD layer may be deposited in one or more deposition operations. In some implementations, a planarization tool may be used to perform a planarization operation (e.g., a CMP operation) to planarize an ILD layer after the ILD layer is deposited.

A deposition tool may be used to deposit an ESL using a PVD technique, an ALD technique, a CVD technique, an oxidation technique, and/or another suitable deposition technique. An ESL may be deposited in one or more deposition operations. In some implementations, a planarization tool may be used to perform a planarization operation (e.g., a CMP operation) to planarize an ESL after the ESL is deposited.

Recesses may be formed through the ILD layer(s) and the ESL(s). The recesses may be formed over the bottom electrode layers 826, over the top electrode layers 828, over the active region 832, over the gate structures 834, and over the resistive structure 830.

In some implementations, a pattern in a photoresist layer is used to etch the ILD layer(s) and the ESL(s) to form the recesses. In these implementations, a deposition tool may be used to form the photoresist layer on the topmost ILD layer. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) and the ESL(s) based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

Conductive structures 808-824, 838, 840, 842, 844, 850 and 902 may be formed in the recesses. In some implementations, the conductive structures 850 and 844 are formed in the recesses to form, for example, contacts on bottom electrode layers 826 and contacts on top electrode layers 828, respectively. In this case, the conductive structures 840 may be interconnect structures in a first via level (e.g., V1) instead of in a second via level e.g., V2). Source/drain contacts on the source/drain electrodes (e.g., source/drain electrodes 214), gate contacts on the gate structures 834, and resistor contacts on the resistive structure 830 may also be formed in the recesses.

A deposition tool may be used to deposit the source/drain contacts, gate contacts, and resistor contacts using a CVD technique, a PVD technique, an ALD technique, an electroplating technique, and/or another suitable deposition technique. The source/drain contacts, gate contacts, capacitor contacts, and resistor contacts may be deposited in one or more deposition operations. In some implementations, a seed layer is first deposited, and a source/drain contact, gate contact, capacitor contact, and/or resistor contact is deposited on the seed layer. In some implementations, a liner (e.g., an adhesion liner, a barrier liner) is first deposited, and a source/drain contact, gate contact, capacitor contact, and/or resistor contact is deposited on the liner. In some implementations, a planarization tool is used to perform a planarization operation (e.g., a CMP operation) to planarize the source/drain contacts, gate contacts, and resistor contacts after the source/drain contacts, gate contacts, and resistor contacts are deposited.

As indicated above, FIGS. 9A-9C are provided as examples. Other examples may differ from what is described with regard to FIGS. 9A-9C.

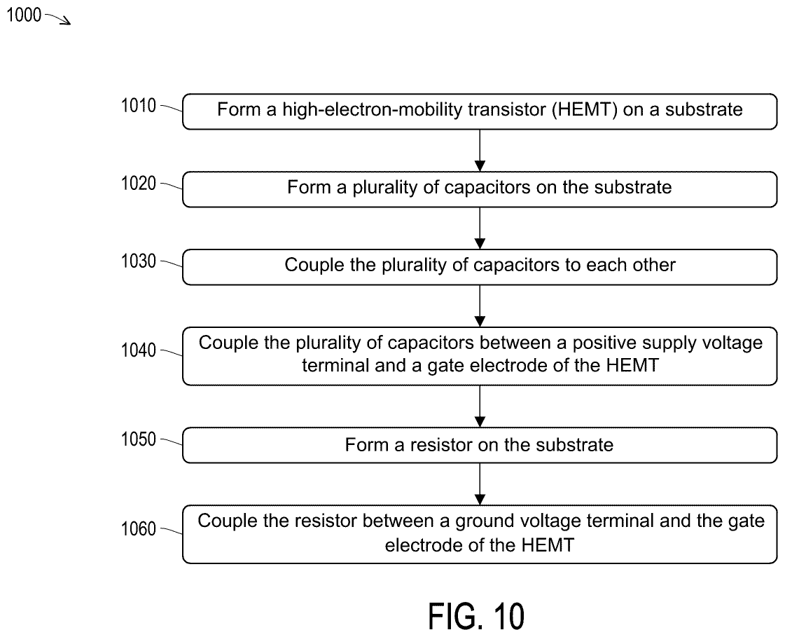

FIG. 10 is a flowchart of an example process 1000 associated with forming a semiconductor device. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a high-electron-mobility transistor (HEMT) on a substrate (block 1010). For example, one or more semiconductor processing tools may be used to form a HEMT (e.g., high voltage HEMT 108) on a substrate (e.g., substrate 202, 302, 802), as described herein.

As further shown in FIG. 10, process 1000 may include forming a plurality of capacitors on the substrate (block 1020). For example, one or more semiconductor processing tools may be used to form a plurality of capacitors (e.g., capacitors 104) on the substrate, as described herein.

As further shown in FIG. 10, process 1000 may include coupling the plurality of capacitors to each other (block 1030). For example, one or more semiconductor processing tools may be used to couple the plurality of capacitors to each other, as described herein.

As further shown in FIG. 10, process 1000 may include coupling the plurality of capacitors between a positive supply voltage terminal and a gate electrode of the HEMT (block 1040). For example, one or more semiconductor processing tools may be used to couple the plurality of capacitors between a positive supply voltage terminal (e.g., conductive structure 304, 804) and a gate electrode (e.g., gate electrode 212) of the HEMT, as described herein.

As further shown in FIG. 10, process 1000 may include forming a resistor on the substrate (block 1050). For example, one or more semiconductor processing tools may be used to form a resistor (e.g., resistor 106) on the substrate, as described herein.

As further shown in FIG. 10, process 1000 may include coupling the resistor between a ground voltage terminal and the gate electrode of the HEMT (block 1060). For example, one or more semiconductor processing tools may be used to couple the resistor between a ground voltage terminal (e.g., conductive structure 306, 806) and the gate electrode of the HEMT, as described herein.

Process 1000 may include additional implementations, such as any single implementation or any combination of implementations described below and/or in connection with one or more other processes described elsewhere herein.

In a first implementation, process 1000 includes coupling the resistor to a terminal of a capacitor of the plurality of capacitors.

In a second implementation, alone or in combination with the first implementation, process 1000 includes coupling a first source/drain electrode (e.g., source/drain electrode 214) of the HEMT to the positive supply voltage terminal, and coupling a second source/drain electrode (e.g., source/drain electrode 214) of the HEMT to the ground voltage terminal.

In a third implementation, alone or in combination with one or more of the first and second implementations, the plurality of capacitors are coupled between the positive supply voltage terminal and the gate electrode through a plurality of first metallization structures (e.g., first metallization structures 224, conductive structures 308, 310, 314, 808, 812) in a first metallization level, where the first source/drain electrode is coupled to the positive supply voltage terminal through a second metallization structure (e.g., second metallization structure 226, conductive structure 320, 322) in a second metallization level, and where the second source/drain electrode is coupled to the ground voltage terminal through an additional second metallization structure (e.g., second metallization structure 226, conductive structure 320, 322, 818, 820) in the second metallization level.

In a fourth implementation, alone or in combination with one or more of the first through third implementations, the resistor is coupled between the ground voltage terminal and the gate electrode through a plurality of first metallization structures (e.g., conductive structures 312, 314, 316, 318, 810, 812, 814, 816) in a first metallization level, where the first source/drain electrode is coupled to the positive supply voltage terminal through a second metallization structure in a second metallization level, and where the second source/drain electrode is coupled to the ground voltage terminal through an additional second metallization structure in the second metallization level.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, an ESD protection circuit includes a high voltage GaN-based HEMT and a plurality of capacitors interconnected with each other in a stacked arrangement. The stacked arrangement of capacitors is connected between VDD and the gate of the HEMT (e.g., before the high side of the gate of the HEMT). In addition, a resistor is connected between VSS and the gate of the HEMT and is connected in series with the stacked capacitor arrangement. During normal operation, the capacitors in the stack are open, and the gate is pulled (e.g., connected) to VSS. As a result, the stacked capacitors provide sufficient voltage drop between VDD and the gate of the high voltage GaN-based HEMT during normal operation so that current leakage may be limited and/or prevented. When there is an ESD event, the capacitors in the stack are shorted, and the gate is pulled (e.g., connected) to VDD so that the gate of the HEMT receives a voltage corresponding to an ESD event as an input voltage. As a result, the high voltage GaN-based HEMT may be successfully turned-on to conduct and dissipate ESD current. Accordingly, an ESD protection device that includes a stacked arrangement of capacitors interconnected with each other and connected between VDD and the gate of the HEMT may fully dissipate ESD event current or provide functionality during normal operating conditions, leading to improved performance and adequate responses to ESD events.

As described in greater detail above, some implementations described herein provide a semiconductor device. The semiconductor device includes a high-electron-mobility transistor (HEMT). The semiconductor device includes a plurality of capacitors in a stacked arrangement, where the plurality of capacitors are connected to each other and connected between a positive supply voltage and a gate of the HEMT. The semiconductor device includes a resistor, where the resistor is connected between a ground voltage and the gate of the HEMT.

As described in greater detail above, some implementations described herein provide a method. The method includes forming a high-electron-mobility transistor (HEMT) on a substrate. The method includes forming a plurality of capacitors on the substrate. The method includes coupling the plurality of capacitors to each other. The method includes coupling the plurality of capacitors between a positive supply voltage terminal and a gate electrode of the HEMT. The method includes forming a resistor on the substrate. The method includes coupling the resistor between a ground voltage terminal and the gate electrode of the HEMT.

As described in greater detail above, some implementations described herein provide a semiconductor device. The semiconductor device includes an electrostatic discharge (ESD) protection circuit, where the ESD protection circuit includes a gallium nitride-based transistor, a plurality of interconnected capacitors connected between a positive supply voltage and a gate of the gallium nitride-based transistor, and a resistor connected between a negative supply voltage and the gate of the gallium nitride-based transistor.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a high-electron-mobility transistor (HEMT);
a plurality of capacitors in a stacked arrangement,
wherein the plurality of capacitors are connected to each other and connected between a positive supply voltage and a gate of the HEMT; and
a resistor,
wherein the resistor is connected between a ground voltage and the gate of the HEMT.

2. The semiconductor device of claim 1, wherein the resistor is connected in series with the plurality of capacitors.

3. The semiconductor device of claim 1, wherein the plurality of capacitors comprise a plurality of HEMT-type capacitors, and
wherein each of the plurality of HEMT-type capacitors comprises:
a first terminal comprising a gate electrode; and
a second terminal comprising a first source/drain electrode connected to a second source/drain electrode.

4. The semiconductor device of claim 3, wherein the first terminal of a first HEMT-type capacitor of the plurality of HEMT-type capacitors in the stacked arrangement is connected to a second terminal of a second HEMT-type capacitor of the plurality of HEMT-type capacitors in the stacked arrangement.

5. The semiconductor device of claim 1, wherein the plurality of capacitors comprises a plurality of metal-insulator-metal (MIM) capacitors,
wherein each of the plurality of MIM capacitors comprises:
a first terminal comprising a first conductive layer; and
a second terminal comprising a second conductive layer,
wherein the first terminal of a first MIM capacitor of the plurality of MIM capacitors in the stacked arrangement is connected to a second terminal of a second MIM capacitor of the plurality of MIM capacitors in the stacked arrangement.

6. The semiconductor device of claim 1, wherein a quantity of the plurality of capacitors in the stacked arrangement is included in a range of 3 to 10.

7. The semiconductor device of claim 1, wherein the HEMT comprises:
a gate electrode;
a first source/drain electrode; and
a second source/drain electrode,
wherein a distance between the gate electrode and the first source/drain electrode is smaller than a distance between the gate electrode and the second source/drain electrode.

8. The semiconductor device of claim 1, wherein the resistor comprises gallium nitride (GaN).

9. The semiconductor device of claim 1, wherein the resistor comprises at least one of silicon chromium (SiCr), silicon (Si), or titanium nitride (TiN).

10. The semiconductor device of claim 1, wherein a first source/drain region of the HEMT is connected to the positive supply voltage, and
wherein a second source/drain region of the HEMT is connected to the ground voltage.

11. A method, comprising:
forming a high-electron-mobility transistor (HEMT) on a substrate;
forming a plurality of capacitors on the substrate;
coupling the plurality of capacitors to each other;
coupling the plurality of capacitors between a positive supply voltage terminal and a gate electrode of the HEMT;
forming a resistor on the substrate; and
coupling the resistor between a ground voltage terminal and the gate electrode of the HEMT.

12. The method of claim 11, further comprising coupling the resistor to a terminal of a capacitor of the plurality of capacitors.

13. The method of claim 11, further comprising:
coupling a first source/drain electrode of the HEMT to the positive supply voltage terminal; and
coupling a second source/drain electrode of the HEMT to the ground voltage terminal.

14. The method of claim 13, wherein the plurality of capacitors are coupled between the positive supply voltage terminal and the gate electrode through a plurality of first metallization structures in a first metallization level,
wherein the first source/drain electrode is coupled to the positive supply voltage terminal through a second metallization structure in a second metallization level, and
wherein the second source/drain electrode is coupled to the ground voltage terminal through an additional second metallization structure in the second metallization level.

15. The method of claim 13, wherein the resistor is coupled between the ground voltage terminal and the gate electrode through a plurality of first metallization structures in a first metallization level,
wherein the first source/drain electrode is coupled to the positive supply voltage terminal through a second metallization structure in a second metallization level, and
wherein the second source/drain electrode is coupled to the ground voltage terminal through an additional second metallization structure in the second metallization level.

16. A semiconductor device, comprising:
an electrostatic discharge (ESD) protection circuit, wherein the ESD protection circuit comprises:
a gallium nitride-based transistor;
a plurality of interconnected capacitors connected between a positive supply voltage and a gate of the gallium nitride-based transistor; and
a resistor connected between a negative supply voltage and the gate of the gallium nitride-based transistor.

17. The semiconductor device of claim 16, wherein the resistor comprises:
a first heterojunction layer;
a second heterojunction layer; and
a two-dimensional electron gas (2DEG) region between the first heterojunction layer and the second heterojunction layer.

18. The semiconductor device of claim 16, wherein each of the plurality of interconnected capacitors comprises:
a first heterojunction layer;
a second heterojunction layer; and
a two-dimensional electron gas (2DEG) region between a portion of the first heterojunction layer and a portion of the second heterojunction layer.

19. The semiconductor device of claim 18, wherein each of the plurality of interconnected capacitors further comprises:
a doped gallium nitride (GaN) layer on the second heterojunction layer;
a first terminal on the doped gallium nitride (GaN) layer,
wherein the first terminal comprises a first electrode; and
a second terminal on the second heterojunction layer,
wherein the second terminal comprises a second electrode and a third electrode, and
wherein the second electrode is coupled to the third electrode.

20. The semiconductor device of claim 18, wherein the first heterojunction layer comprises gallium nitride (GaN), and
wherein the second heterojunction layer comprises aluminum gallium nitride (AlGaN).
